(19) United States
(12) Patent Application Publication
(10) Pub. No.: US 2023/0097786 A1
(43) Pub. Date: Mar. 30, 2023

(54) MEMS FLOW MICROPHONE WITH EQUAL ACOUSTIC PATH LENGTHS

(71) Applicant: Soundskrit Inc., Montreal (CA)

(72) Inventors: Stephane Leahy, Montreal (CA); Sahil Gupta, Montreal (CA); Wan-Thai Hsu, Saline, MI (US); Frederic Lepoutre, Montreal (CA)

(21) Appl. No.: 17/908,461

(22) PCT Filed: Mar. 8, 2021
(86) PCT No.: PCT/CA2021/050308

§ 371 Date: Aug. 31, 2022

Related U.S. Application Data
(60) Provisional application No. 62/986,391, filed on Mar. 6, 2020.

(51) Int. Cl. B81B 7/00; H04R 1/38

(52) U.S. Cl. CPC B81B 7/0061; H04R 1/38; B81B 2201/0257

(57) ABSTRACT

A device includes a housing, an acoustic sensor disposed within the housing, the acoustic sensor comprising a microelectrornechanical (MEMS) transducer, a first port in the housing establishing a first acoustic path for air flow to the MEMS transducer, and a second port in the housing establishing a second acoustic path for air flow to the MEMS transducer. The first and second acoustic paths have an equal path length.

### CROSS-REFERENCE TO RELATED APPLICATION

This application claims the benefit of U.S. provisional application entitled “MEMS Flow Microphone with Side-by-Side Sound Ports,” filed Mar. 6, 2020, and assigned Ser. No. 62/986,391, the entire disclosure of which is hereby expressly incorporated by reference.

### BACKGROUND OF THE DISCLOSURE

### Field of the Disclosure

The disclosure relates generally to microelectromechanical (MEMS) microphones.

### Brief Description of Related Technology

Traditional omnidirectional microphones measure the pressure of incoming sound. A transducer, or membrane, that moves in response to the incoming sound is encapsulated in a package. The transducer partitions the package into two air volumes, a front volume and back volume. The microphone package has a sound port that couples one of the volumes of air to the outside ambient air. As sound hits the microphone, the sound couples into one of the air volumes through the sound port and changes the pressure. This creates a difference in pressure between the front volume and back volume that creates a force on the transducer and drives its motion. In this configuration, the omnidirectional microphone responds equally to sound travelling at all directions.

Directional microphones are designed to have high sensitivity to sound travelling in one direction and low sensitivity to sound travelling in another direction. Directionality allows the microphone to separate sound sources. In order to create a directional microphone, a second sound port is incorporated into the microphone package. One sound port couples the front volume to the ambient air, while a second sound port couples the back volume to the ambient air at a location separated from the first sound port by a fixed distance. One such type of microphone is an electret microphone.

Directional microphones have been realized with microelectromechanical (MEMS) components. In one implementation, two omnidirectional MEMS microphones are used to mimic the response of a directional microphone. The omnidirectional MEMS microphones are spaced apart so that the pressure of the ambient sound is measured at two points in space. By looking at the difference in pressure between these two points (e.g., the pressure gradient), directionality can be achieved. Other MEMS devices use a single omnidirectional microphone with two sound ports on either side of the membrane (e.g., each coupled to the front volume and back volume of the package respectively). The operation of these devices work similarly to the directional electret microphone previously described.

Directional sound sensing with pressure-based microphones presents fundamental challenges. The transducers for these microphones are driven by the pressure gradient forces in the sampled sound field. When the sound ports of these devices are close together, as is the case with most MEMS devices, the pressure gradient between the sound ports is very small, resulting in very low sensitivity in the microphone. This effect becomes even more pronounced at low frequencies where the incoming sound has a large wavelength. The larger the wavelength of sound, the smaller the pressure gradient between two fixed points, and thus the lower the sensitivity of the microphone. In order to remedy this, the sound ports are placed at a far distance from one another, to increase the difference in pressure. This not only increases system size, but also suffers from aliasing effects at higher frequencies. Incoming sound with wavelengths smaller than twice the distance between the sound ports will suffer from aliasing and so the microphone's ability to pick up a directional signal at those frequencies will be compromised. Thus, it is difficult to make a directional microphone with good sensitivity and directionality across a wide range of frequencies.

Microphones have been designed to respond to differences in air flow rather than pressure. A hot wire microphone has used two wires heated to very high temperatures. As sound hits the microphone, the air hits the first wire and cools it down. This interaction also heats up the surrounding air. As the sound continues to travel it hits the second wire. Because the air that interacts with the second wire is now warmer, it does not cool down the second wire as much as the first. Sound travelling parallel to the direction of the two wires thereby creates a larger temperature differential than sound flowing perpendicular. Thus, the hot wire microphone is used to determine direction.

Microphone transducers have been designed to respond to the viscous drag forces associated with air flow. By allowing for the air to flow through the transducer, the air creates a drag force (i.e., friction) on the mechanical transducer and pulls the transducer in the same direction as the travelling air, or sound. This microphone is thus directional. Designing a transducer that responds to this viscous force overcomes some of the limitations of traditional pressure-based microphones. Specifically, the viscous force on sufficiently thin transducers does not change significantly as a function of frequency. Thus, it is possible to design a directional microphone based on the viscous interactions with air flow that is able to maintain high sensitivity across a wide range of frequencies.

### SUMMARY OF THE DISCLOSURE

In accordance with one aspect of the disclosure, a device includes a housing, an acoustic sensor disposed within the housing, the acoustic sensor including a microelectromechanical (MEMS) transducer, a first port in the housing establishing a first acoustic path for air flow to the MEMS transducer, and a second port in the housing establishing a second acoustic path for air flow to the MEMS transducer. The first and second acoustic paths have an equal path length.

In accordance with another aspect of the disclosure, a device includes a housing, an acoustic sensor disposed within the housing, the acoustic sensor including a first microelectromechanical (MEMS) transducer and a second MEMS transducer, a first port in the housing establishing a first acoustic path for air flow to the first MEMS transducer, and a second port in the housing establishing a second acoustic path for air flow to the second MEMS transducer. The first and second acoustic paths have an equal path length.

In connection with any one of the aforementioned aspects, the devices described herein may alternatively or additionally include or involve any combination of one or more of the following aspects or features. The MEMS transducer is configured as a flow transducer through which air flows. The housing includes a surface in which the first and second ports are formed. The first and second ports are disposed side by side. The surface is planar. The first and second ports are oriented in a plane. The surface is disposed along an edge of the enclosure. The housing includes first and second surfaces in which the first and second ports are formed, respectively. The first and second surfaces define a corner or edge of the housing. The device further includes an enclosure disposed within the housing, the enclosure encapsulating the MEMS transducer. The acoustic sensor includes a printed circuit board on which the MEMS transducer is disposed, the printed circuit board including first and second sound ports for the first and second acoustic paths, respectively. The MEMS transducer includes a sensing structure oriented transversely to the substrate. The first sound port is configured to define a bend in the first acoustic path within the printed circuit board. The first and second ports in the housing are larger than the first and second sound ports in the printed circuit board. The first and second acoustic paths lead to opposite sides of the MEMS transducer. The device further includes an acoustic delay element disposed along the first acoustic path. The acoustic sensor includes a printed circuit board on which the MEMS transducer is disposed. The acoustic delay element is disposed between the printed circuit board and the MEMS transducer. The device further includes a product housing in which the housing and the acoustic sensor are disposed. The housing includes an enclosure for the acoustic sensor. The product housing includes a hole that couples air to the first and second ports. The acoustic sensor includes an enclosure in which the first and second MEMS transducers are disposed, an integrated circuit disposed within the enclosure, and a dividing wall that isolates a volume for the first and second MEMS transducers from a volume for the integrated circuit. The housing is configured as a product housing. A spacing between the first and second ports is greater than or about equal to a depth of the MEMS transducer relative to a surface of the product housing in which the first and second ports are formed. The acoustic sensor includes an integrated circuit configured to determine a difference between outputs of the first and second MEMS transducers. The first and second MEMS transducers are configured to capture sound propagating along a first direction. The acoustic sensor includes third and fourth MEMS transducers configured to capture further sound propagating along a second direction. The first and second directions are orthogonal to one another.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 is a block diagram of an acoustic environment containing a directional microphone in accordance with one example.

FIG. 2 depicts a MEMS flow microphone mounted on the bottom side of a product enclosure in accordance with one example.

FIG. 3 is a cross-sectional, schematic view of a MEMS flow microphone mounted on the bottom side of a product enclosure in accordance with one example.

FIG. 4 is a cross-sectional, schematic view of a MEMS flow microphone with planar or other side-by-side sound ports in accordance with one example.

FIG. 5 is a cross-sectional, schematic view of a MEMS flow microphone with a MEMS sensor positioned and configured to establish equal acoustic path lengths to planar or other side-by-side sound ports in accordance with one example.

FIG. 6 is a cross-sectional, schematic view of a MEMS flow microphone with a MEMS sensor disposed in packaging configured to establish equal acoustic path lengths to planar or other side-by-side sound ports in accordance with one example.

FIG. 7 is a cross-sectional, schematic view of a MEMS flow microphone with a MEMS sensor disposed in packaging configured to establish equal acoustic path lengths to planar or other side-by-side sound ports in accordance with another example.

FIG. 8 is a cross-sectional, schematic view of a MEMS flow microphone with a MEMS sensor disposed in packaging configured to establish equal acoustic path lengths to planar or other side-by-side sound ports in accordance with another example.

FIG. 9 depicts cross-sectional, schematic views of examples of MEMS flow microphones with acoustic delay elements to establish equal acoustic path lengths to planar or other side-by-side sound ports in accordance with another example.

FIG. 10 depicts cross-sectional, schematic views of examples of MEMS flow microphones with acoustic delay elements to establish equal acoustic path lengths to planar or other side-by-side sound ports.

FIG. 11 is a cross-sectional, schematic view of a MEMS flow microphone with multiple MEMS sensors and planar or other side-by-side sound ports in accordance with one example.

FIG. 12 depicts several schematic views of a MEMS flow microphone having multiple MEMS sensors disposed in a symmetrical acoustic chamber in accordance with one example.

FIG. 13 is a cross-sectional, schematic view of a MEMS flow microphone with acoustic channels configured with planar or other side-by-side sound ports to increase the sensitivity of the MEMS flow microphone in accordance with one example.

FIG. 14 depicts a cross-sectional, schematic view of a MEMS flow microphone with side-by-side sound ports coupled to a product with non-planar sound ports that lay on different surfaces of the product in accordance with one example.

FIG. 15 depicts schematic views of a MEMS flow microphone with planar or other side-by-side sound ports in accordance with another example.

FIG. 16 depicts cross-sectional, schematic views of a MEMS flow microphone with planar or other side-by-side sound ports in accordance with another example

FIG. 17 depicts schematic (perspective) views of a MEMS flow microphone with multiple MEMS sensors and planar or other side-by-side sound ports in accordance with another example,

FIG. 18 depicts schematic (perspective) views of a MEMS flow microphone with multiple MEMS sensors and planar or other side-by-side sound ports in accordance with yet another example,

FIG. 19 depicts schematic (top) views of a MEMS flow microphone with multiple MEMS sensors and planar or other side-by-side sound ports in accordance with yet another example.

FIG. 20 depicts schematic (top) views of a MEMS flow microphone with multiple MEMS sensors and planar or other side-by-side sound ports in accordance with yet another example.

The embodiments of the disclosed devices may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

MEMS flow microphones with equal path lengths are described. In some cases, the equal path lengths may extend from planar or other side-by-side sound ports. At least two sound ports are included to allow air to flow through the package and excite a MEMS sensor. The MEMS flow microphones include an enclosure or package having a planar or other side or surface in or along which the sound ports are disposed. The sound ports are thus facing the same direction and are accordingly referred to herein as “side-by-side” sound ports (in contrast to, for instance, ports on opposing sides). Having side-by-side sound ports (e.g., along the same planar or other surface or side) allows the microphone to be more conveniently mounted in, or otherwise integrated with, another device, such as a portable electronic device. The size of such electronic devices may also present limitations on the size of the microphone package. The flow-based nature of the disclosed microphones allows the sound ports to be close to one another, thereby allowing the microphone package to comply with any such size limitations.

The disclosed microphones may include one or more features of the package and/or other components directed to supporting the directionality of the MEMS sensor. For example, the features may ensure that the directionality is unaffected by resonance modes of the package. In some cases, the package, the MEMS sensor, and/or other elements of the microphone is/are configured so that the acoustic path length from the sound inlet to the MEMS sensor is of equal (e.g., approximately or otherwise effectively equal) length as the path length from the sound outlet to the MEMS sensor, either from physical placement or the use of acoustic delay elements. Alternatively or additionally, the disclosed microphones may include multiple sensing structures configured for operation in a differential mode to effectively cancel the signal induced from unwanted resonances. In these and other cases, the sensor performance may not be heavily influenced by the spacing between the sound inlet and outlet. As a result, the disclosed microphones may be configured such that multiple (e.g., all) sound ports of the microphone are enclosed by a single acoustic channel, thereby facilitating the integration of the sensor into an electronic or other device.

In accordance with another aspect, the disclosed microphones may avoid the use of tubes to redirect the air flow. The absence of tubes in turn, minimizes or lowers the complexity of manufacturing the microphone package. However, in other cases, one or more tubes may be used in the microphone package of the disclosed devices, e.g., to further improve air flow and device performance. Tubes may be used to couple the sound ports of the microphone to sound ports in the product housing in any arbitrary location.

The disclosed microphones may be useful in a wide variety of applications and contexts, including, for instance, various consumer devices such as smartphones, laptops, and earbuds. The configuration of the disclosed microphones may be useful in connection with any device in which there is an interest in listening to sound originating from a specific direction with greater sensitivity than sound originating from other directions. The configuration of the disclosed microphones may also be useful in connection with any device in which there is an interest in limiting the number of acoustic channels and, thus, holes, formed in the electronic device. With all of the sound ports disposed along a single (e.g., planar) surface or side, incorporation of the disclosed devices does not force the electronic device to have holes placed, e.g., along multiple edges or sides of the device. However, in some cases, the microphone with sound ports disposed along a single surface or side may allow for incorporation into an electronic device with holes along multiple edges or side of the device. In some instances, where all the sound ports are on a single surface or side of the microphone, and close enough to fit into a single acoustic channel drilled into the electronic device, the disclosed microphones may be readily integrated into a wide variety of devices.

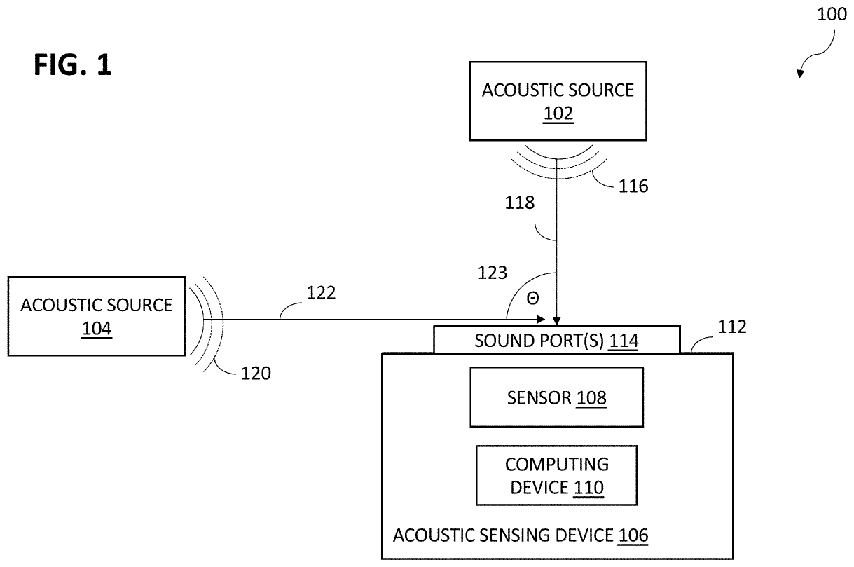

FIG. 1 is a block diagram of an acoustic sensing environment 100 in accordance with one example. Acoustic sensing environment 100 includes acoustic waves 116 and 120 emitted by a first acoustic source 102 and second acoustic source 104 respectively and are received or captured by the acoustic sensing device 106. Acoustic waves 116 are propagated radially and include direct path 118, Acoustic waves 120 are propagated radially and include direct path 122 at an angle 123 from direct path 116. Acoustic sensing device 106 may be an electronic device such as a smartphone, personal computer, headset, TV, robot, etc. Embedded inside device 106 is an acoustic sensor 108 and computing device 110. The sensor 108 is configured to capture or sense acoustic waves and computing device 110 is configured to process and analyze the sensed acoustic waves. The device 106 has an edge 112 on which one or more sound ports 114 lay and couple the acoustic sensor 108 to the acoustic waves 116 and 120. In some instances, one or more of the sound ports 114 may lay on edge 112 of the acoustic sensing device 106 and an additional one or more sound ports may lay on a different edge of acoustic sensing device 106. Acoustic waves 120 travel along a path 122 that is parallel to the edge 112, while acoustic waves 116 travel along a path 118 that is perpendicular to the edge 112. The following describes a packaging configuration in which the acoustic sensor 108 captures the portion of the acoustic environment 100 with acoustic waves 120 parallel to edge 112 with increased sensitivity relative to the portion of the acoustic environment 100 with acoustic waves 116. For example, the sensor 108 may capture acoustic waves 120 with at least 20 dB greater sensitivity than acoustic waves 116. In this sense, the sensor 108 is said to be directional. In some instances, the acoustic waves 116 and 120 may emanate from a combination of different acoustic sources in environment 100.

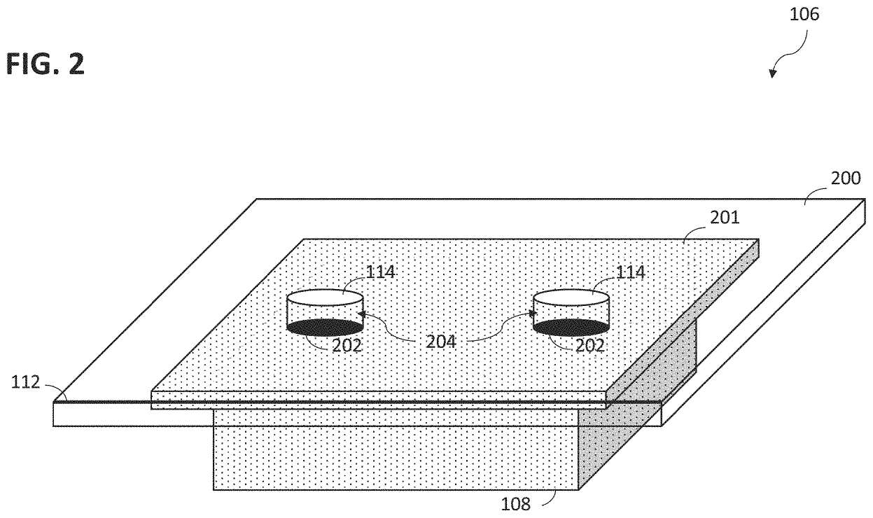

FIG. 2 depicts the acoustic sensing device 106 with an embedded acoustic sensor 108. The acoustic sensor 108 may be a microphone, for example. The housing of device 106 has a surface 200 containing edge 112. The sensor 108 is coupled to the surface 200 through mounting structure 201 such as a printed circuit board. The mounting structure 201 may contain multiple printed circuit boards as well as adhesive layers, acoustic meshes, and gaskets as typically used in combination with MEMS microphones not shown. In one example of the disclosed devices, surface 200 contains two sound ports 114 which lay on an axis parallel to edge 112 and allow air to flow from the external acoustic environment into the sensor 108. The two sound ports 114 on surface 200 of the device 106 are coupled to sound ports 202 on mounting structure 201 through acoustic channels 204. Air flow in the external environmental parallel to edge 112 creates a pressure difference at sound ports 114. This results in air flow into acoustic channels 203, through sound ports 202 and microphone 108. Surface 200 may be a housing for acoustic sensing device, or the product 106. It may be made of any combination of a metal, plastic, or any other material commonly used in product housings such as those used in consumer electronic devices. In alternative examples of the disclosed devices, surface 200 may be non-flat. For example, it may be curved as with devices such as earbuds.

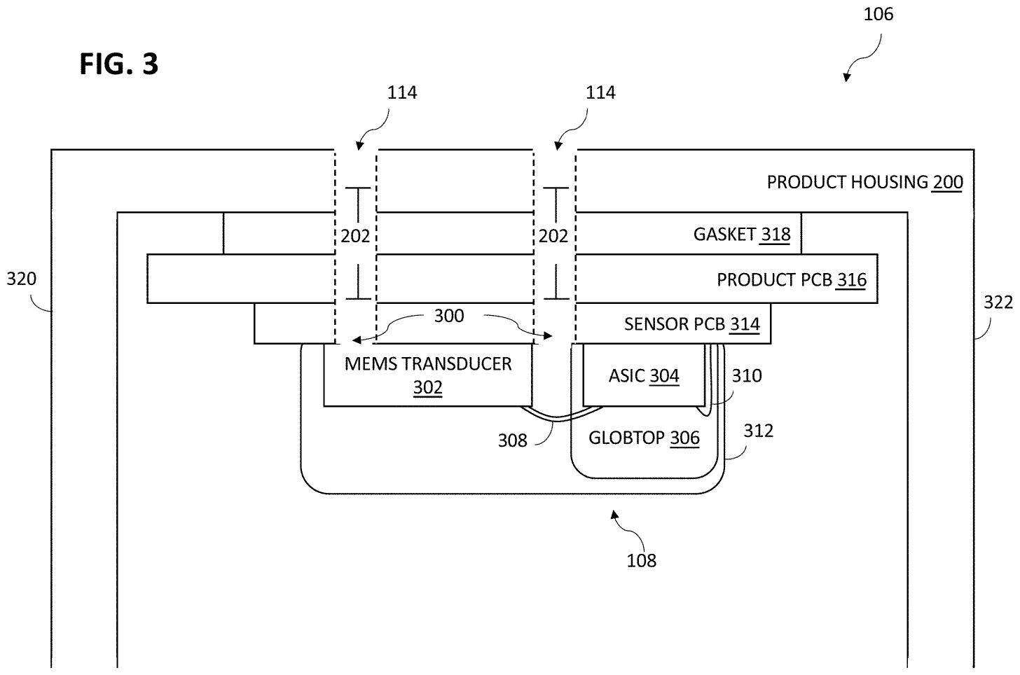

FIG. 3 describes in more detail one example in which the sensor 108 is a bottom port MEMS microphone coupled to the housing 200 of device 106. The acoustic sensor 108 contains a MEMS transducer 302 that vibrates in response to impinging acoustic waves and is connected to an application-specific integrated circuit (ASIC) 304 via wire bonds 308. The MEMS transducer 302 and ASIC 304 are both attached to a printed circuit board (PCB) 314. The PCB 314 may include conductive traces to electrically couple the ASIC 304 to the PCB 314 through wire bonds 310. The ASIC 304 is further encapsulated by globtop 306 for protective purposes. The MEMS transducer 302 and ASIC 304 are covered by a lid 312 that creates an acoustic seal with PCB 314. In one instance, the lid 312 is made of metal. In another instance, the lid 312 may be a printed circuit board, a ceramic, or a plastic. The microphone 108 consists of the lid 312, sensor PCB 314, and internal components (MEMS transducer 302, ASIC 304, etc.). The sensor PCB 314 may be coupled to a second printed circuit board 316 containing sensor 108 in addition to other electronics present in device 106. The product PCB 316 may contain conductive traces electrically coupled to those of sensor PCB 314 (e.g., via solder). The conductive traces of PCB 316 may connect the output of sensor 108 to a computing device for further processing. Finally, a gasket 318 may be couple the product PCB 316 to the housing 200. The gasket may be made of rubber or any other material commonly used with MEMS microphones. The gasket may be attached to the housing 200 and PCB 316 through an adhesive layer or through compression. In between any of the layers 200, 318, 316, 314 there may be an acoustic mesh to protect the MEMS transducer 302 from particle or liquid ingress. The product housing 200 contains one or more sound ports 114 that allow air to flow from the external environment into sensor 108. The sound ports 114 provide an opening to acoustic channels 202 that extend through the gasket 318, product PCB 316, and to sound ports 300 of the sensor PCB 314. This couples the air volume enclosed between the lid 312 and sensor PCB 314 to the external acoustic environment. In alternative examples, the gasket 318 may include two separate gaskets each coupled to the acoustic channel of each of the two sound ports 314. Product housing 200 may have a rectangular, curved, circular, elliptical, or any other geometric profile. The sound ports 300 of the microphone 108 are planar or side-by-side sound ports. The sound ports of in the product housing 200 may be planar or non-planar. For example, in some instances, when product housing 200 is curved, sound ports 114 may be non-planar. One or more of the sound ports 114 may lay on one or more of the edges 320 or 322 of product housing 200.

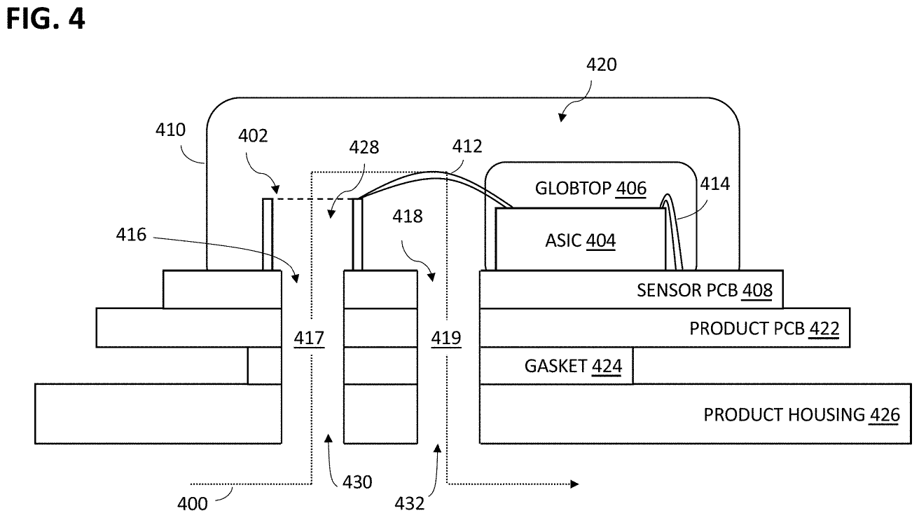

The following figures describe the acoustic channels and internal configuration of sensor 108 to provide sufficient directionality as described in FIG. 1, The purpose of a directional microphone is to have high sensitivity to sound travelling along one direction and low sensitivity to sound travelling in another direction. To achieve this, a directional microphone uses a sensing structure positioned in a package with two sound ports, an inlet and an outlet. While the inlet and outlet may take many positions along the package, in some cases, it is useful to have the sound ports positioned along the same planar surface of the package. This reduces the friction when trying to integrate the microphone into a product such as a smartphone, laptop, TV, speaker, etc. where the manufacturer does not wish to create multiple holes along different edges of the electronic device. FIG. 4 below illustrates an example of a package for a directional microphone in which the two sound ports lay along the same plane.

FIG. 4 depicts a device having side-by-side sound ports in accordance with one example. The device includes a MEMS transducer 402 attached to or otherwise supported by a substrate 408. The substrate 408 may be or include a printed circuit board with one or multiple layers. The device includes an application-specific integrated circuit (ASIC) 404. The ASIC 404 is configured to read out the electrical signal from the MEMS transducer 402 and covered by a protective globtop 406. The ASIC 404 is also attached to the substrate layer 408 and electrically connected to conductive traces on substrate layer 408 by wire bonds 414, and both the MEMS 402 and the ASIC 404 are encapsulated by a lid or other enclosure 410. The lid may be made of a metal material. The MEMS 402 and ASIC 404 may be electrically connected by wire bonds 412, either to each other, or directly to the substrate layer. The MEMS 402, ASIC 404, and lid 410 may also be attached using other methods known to those skilled in the art. In another instance, the MEMS 402 may be attached to the sensor PCB 408 using flip chip technology. Within the microphone PCB 408, two sound ports (e.g., an inlet and outlet) 416 and 418 are provided to allow ambient sound to couple into the enclosed volume of air 420 and 428 formed by the sensor lid 410 and substrate layer 408 and excite the MEMS transducer 402. In this example, the configuration presents a bottom port microphone. The substrate layer, or sensor PCB 408, is further attached to or otherwise supported by a product PCB 422. Finally, a gasket 424 couples the product PCB 422 to the product housing 426. The sound ports 416 and 418 extend through the sensor PCB 408, product PCB 422, and gasket 424 through acoustic channels 417 and 419 respectively and couple to sound ports 430 and 432 embedded in the product housing 426. In this case, both the microphone and product housing have side-by-side sound ports. In some instances, sound ports 416 and 418 may be positioned along a planar surface 408 while sound ports 430 and 432 are positioned along a surface 426 that is non-planar. The product in this case may be an electronic device such as a smartphone or tablet. In other cases, e.g., for a top port microphone, the sound ports 416 and 418 may be placed on the metal lid 410 of the microphone. In this scenario the gasket 424 is used to couple the lid 410 to the product housing 426. In one example of the top port microphone, the MEMS transducer 402 is attached to the lid.

As sound travels along a direction 400 parallel to the axis connecting the sound ports 430 and 432 of the product housing 426 (e.g., along the plane of the surface or along the side in which the ports are disposed), a pressure difference is created across the sound ports 430 and 432 due to the phase difference of the sound wave. In some instances, the pressure difference created may also be due to an amplitude difference in the sound wave at the two ports. In such an instance, the sound wave may be a spherical wave. A pressure difference between sound ports 430 and 432 drives air into and out of the acoustic channels 417 and 419, through the package and associated substrate layers 408, 422, 424, 426 and into the sound ports 416 and 418 of the sensor's substrate layer, or PCB, 408. The MEMS transducer 402 (i.e. microphone) that responds to this airflow may be located within the package above either of the sound ports 416 or 418 to sense the sound wave. The air motion causes the MEMS sensor 402 to oscillate, and the oscillation is transduced into a voltage signal. One method of transduction is capacitive sensing. Other methods of transduction may be used, including, for instance, electromagnetic, piezoelectric, optical or strain sensing.

The MEMS transducer 402 may be a capacitive transducer. For example, the MEMS transducer 402 may include a cantilever or other structure spaced from an electrode to establish a capacitance. In some cases, the cantilever or other structure has a number of holes to allow air to flow through the structure. For example, the MEMS transducer may include a porous diaphragm. The MEMS transducer may be configured in accordance with the capacitive sensor devices described in International Publication Number WO 2019/226958, the entire disclosure of which is hereby incorporated by reference, but other capacitive sensor devices may be used.

Unlike traditional pressure or pressure-gradient based microphones in which the MEMS transducer creates an effective seal within the enclosed package separating the air volume into a front volume and back volume, the transducer 402 allows air to flow freely between air volume 422 and 428 including aft motion excited by sound waves in the frequency range of 20 Hz-20 kHz.

When sound travels in a direction perpendicular to the axis connecting the sound ports 430 and 432, the pressure is the same at the two sound ports, and no air is driven through the sound channels 417 and 419 and associated package. Thus, the sensor only responds to sound travelling across one direction, parallel to the axis on which the sound ports 430 and 432 lay. However, at certain frequencies, the package may resonate (e.g., due to a Helmholtz resonance), and the air moves in and out of the sound ports and acoustic channels in phase, causing an undesired voltage signal. At these frequencies, sound that travels in a direction perpendicular to the axis connecting the sound ports 430 and 432 may enter the acoustic channels 417 and 419 and compromise the directionality of the sensor.

The disclosed devices present several techniques to mitigate the effects of this undesired resonance. As shown in the example of FIG. 4, the acoustic paths (e.g., the path travelled by the acoustic wave) may lead to opposite sides of the MEMS sensing plate or other transducer. If the package (and/or other aspects of the device) is configured such that the acoustic path length from a first sound port, or inlet, to the MEMS sensing plate is equal (e.g., effectively equal) to the path length of the MEMS sensing plate to a second sound port, or outlet, then when the package resonates, the air particles at the sensing plate do not move, and the microphone does not generate an undesired voltage signal. In such a scenario, the alternating airflow seen at the MEMS sensing plate from both sides may destructively interfere, reducing any undesired voltage signal.

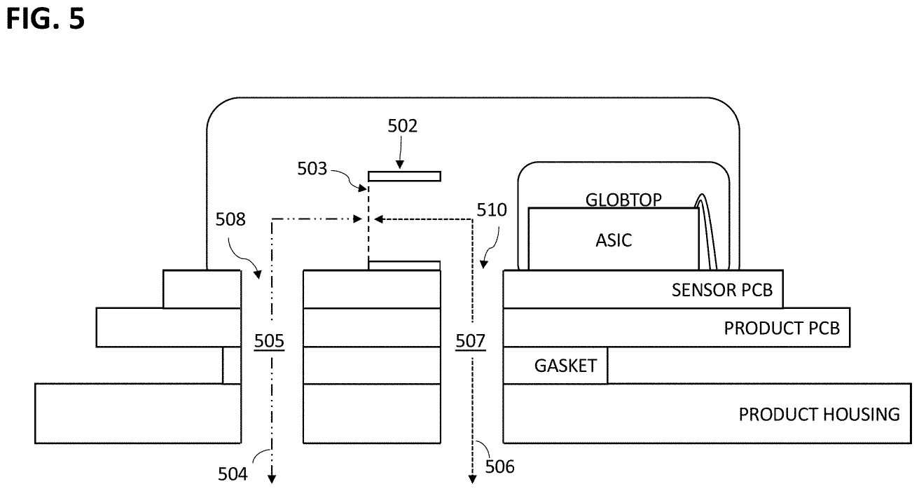

FIG. 5 illustrates one example in which the MEMS sensor 502 is disposed in the middle of the package to equate the two path lengths. In this case, the acoustic path 504 through the package via acoustic channel 505 is of equal length to the acoustic path 506 through the package via acoustic channel 507. The MEMS sensing structure 503 is placed in the center of the total acoustic path (504+506) by flipping or rotating the MEMS die such that the sensing structure 503 is oriented transversely to the printed circuit board of the MEMS sensor 502. Because paths 504 and 506 are of equal length, when air flows through both acoustic channels 505 and 507 in phase due to resonance, no motion is seen at the location of the MEMS sensor 502.

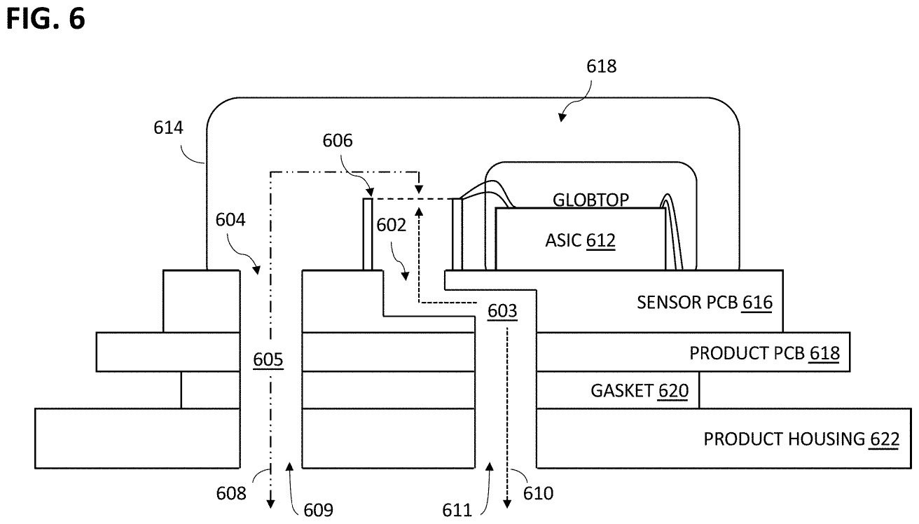

In cases where it is undesirable or impractical to flip or rotate the MEMS die, an asymmetric package may be created such that path length 504 and 506 are equal as depicted in the example of FIG. 6.

A bend in acoustic channel 603 is created through the microphone substrate layer or PCB 616 and coupled to the sound port 602 under the MEMS chip 606 and sound port 611 embedded in the product housing 622. A second acoustic channel 605 is coupled to a second sound port 604 in the sensor PCB 616 and second sound port 609 in the product housing 622, The acoustic channel 603 has a longer acoustic path length than the second acoustic channel 605. The difference in length of the two acoustic channels 603 and 605 compensates for the uneven acoustic path length seen in the air volume 618 enclosed by the microphone lid 614 and PCB 616. As a result, the total acoustic path lengths 608 and 610 from the ambient air to the opposing sides of the MEMS transducer 602 are made equal. Further, by allowing the longer acoustic channel 603 to be positioned on under the ASIC 612, such an example may be provided without increasing the overall size of the microphone enclosure formed by lid 614 and PCB 616, In one instance, the cross-sectional profile of the bent acoustic channel 603 is “L-shaped,” In another instance, the bent acoustic channel may take another cross-sectional profile. In some instances, the bent acoustic channel may meander between two distances until the path length 608 and 610 are equal.

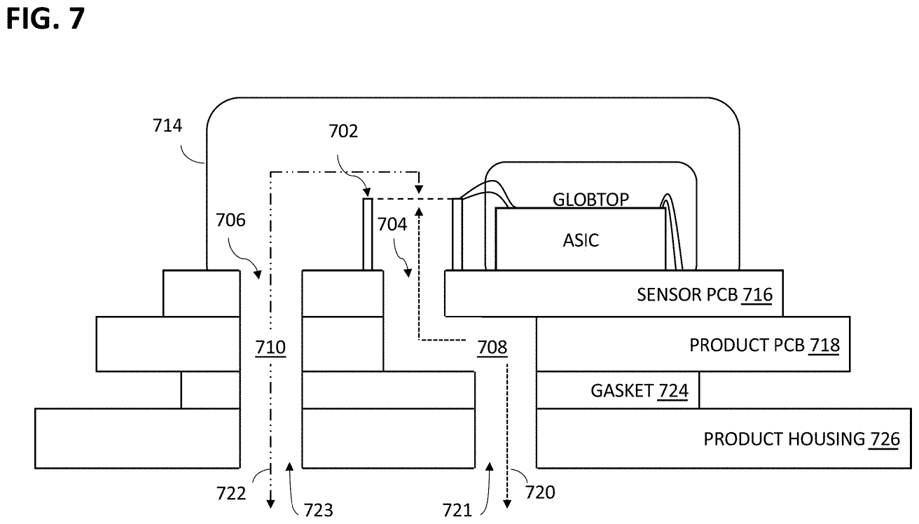

Alternatively, the acoustic path lengths may be equalized by leveraging the product enclosure in which the microphone will be integrated within, as illustrated in the example of FIG. 7. In this case, the microphone formed by lid 714 and the PCB 716 is mounted onto or otherwise supported by a second PCB 718 (e.g., a PCB of the larger device or product). In this example, the MEMS transducer 702 is mounted on or otherwise supported by a substrate layer or PCB 716. Side-by-side sound ports 704 and 706 are embedded inside sensor PCB 716. Sound port 704 lays under MEMS transducer 702 and is coupled to bent acoustic channel 705. The bend in acoustic channel 708 is positioned inside the product PCB 718 on top of which the sensor PCB 716 is mounted. Similarly, the sound port 706 is coupled to acoustic channel 710 inside PCB 718. Acoustic channels 708 and 710 are coupled to sound ports 721 and 723 in product housing 726 that are open to the external environment. In one example, the length of bent acoustic channel 708 is greater than that of acoustic channel 710, By leveraging the extra port length provided by the PCB of the product 718 on which the microphone is mounted, the total acoustic path lengths 720 and 722 from the ambient air to the opposing sides of the MEMS transducer 702 are made equal. In alternative examples of the described devices, the bend in acoustic channel 708 used to increase acoustic path length 722 may be embedded in the gasket 724, product housing 726, or any combination thereof. In some instances, the bent acoustic channel 708 may meander between one or multiple layers 716, 718, 724, 726. In alternative examples, the acoustic channel 710 may also be bent, with a shorter length than bent acoustic channel 708.

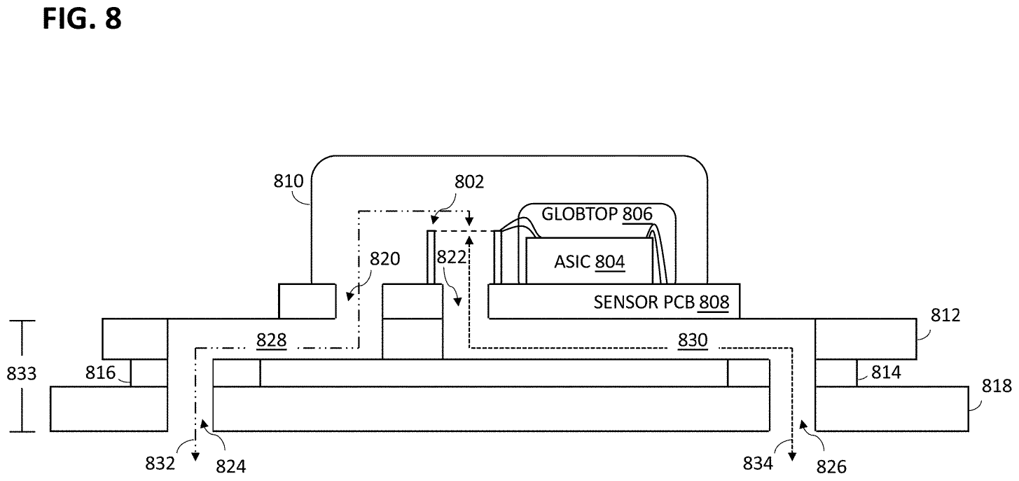

FIG. 8 depicts an alternative example of FIG. 7 with multiple bent acoustic channels. In this example, a microphone having MEMS transducer 802, ASIC 804, globtop 806, sensor PCB 808, and lid 810 is mounted on top of or otherwise supported by a product PCB 812. The product PCB 812 is coupled to the product housing 818 through gaskets 814 and 816. The sensor PCB 808 contains sound ports 820 and 822. In this example, the spacing between the sound ports 824 and 826 embedded in the product housing 818 is larger than the spacing between sound ports 820 and 822. Sound ports 820 and 822 are coupled to sound ports 824 and 826 through bent acoustic channels 828 and 830, respectively. In one instance, acoustic channels 828 and 830 are embedded in the product PCB 812, The acoustic channel 830 is made longer than acoustic channel 828 so that the acoustic path lengths 832 and 834 from the ambient air to the opposing sides of the MEMS transducer 802 are made equal. The thickness 833 is the composite thickness of the product housing 818, gasket 814, product PCB 812 and microphone PCB 808. In some instances, if the thickness 833 is made relatively large, acoustic losses may occur through acoustic channels 828 and 830. Because sound ports 824 and 826 embedded in the product housing 818 lay at a greater distance than ports 820 and 822 in the microphone PCB 808, they see a larger pressure difference and thus drive more airflow through the package to overcome losses experienced in acoustic channels 828 and 830. This may be useful to prevent acoustic related losses when the microphone is embedded deep within the product, or in other words, when thickness 833 is relatively large. In some examples of the disclosed devices, the spacing between ports 824 and 826 may be greater than or equal to the thickness 833. Gaskets 814 and 816 may also be combined into a single gasket.

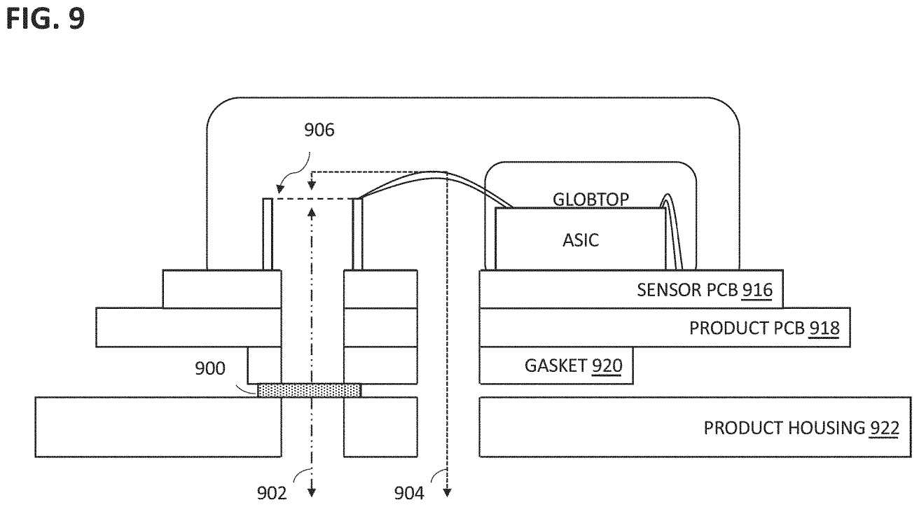

FIG. 9 depicts yet a further example in which an acoustic delay element is added to the shorter physical path to make the path length appear physically longer to incoming acoustic waves. The delay element allows the air to pass through freely, and only delays the phase of the sound appropriately.

The acoustic delay element 900 is placed in the acoustic path 902 leading to the MEMS transducer 906. As shown in FIG. 9, the delay element 900 may be placed between the gasket 920 and product housing 922. In other examples, the delay element 900 may be place between the product PCB 918 and gasket 920 or between the sensor PCB 916 and product PCB 918. The delay element effectively increases the acoustic path 902 to the transducer 906, equalizing the path lengths 902 and 904 on opposing sides of the transducer 906. The delay element 900 may be attached using an adhesive. The delay element 900 may also serve a second purpose for filtering out and protecting the microphone transducer 906 from contaminants such as water, oils, dust, and other sediment. The delay element may alternatively or additional mitigate large pressure swings due to wind, shock, or vibration from propagating to the microphone. In some examples, multiple delay elements may be used between different layers in the product. In other examples, the delay element 900 may be used to alter the polar (or pickup) pattern of the directional microphone.

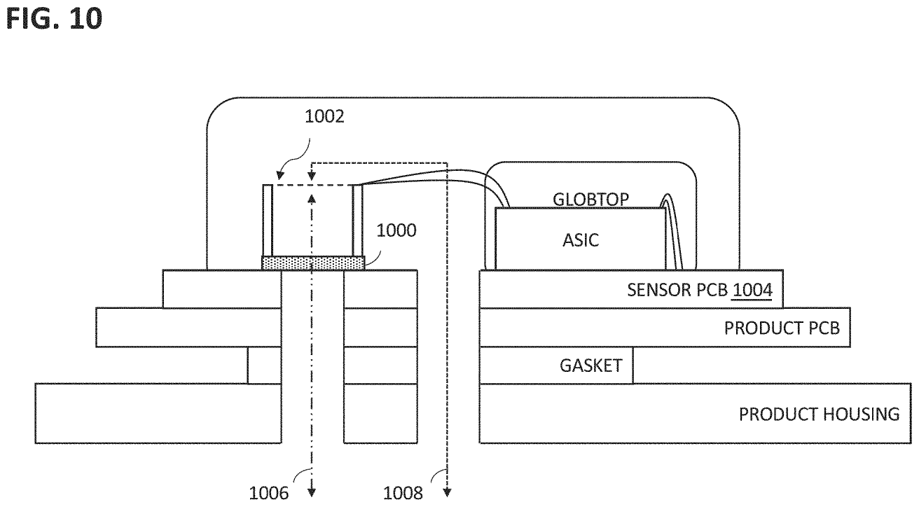

FIG. 10 illustrates another example where an acoustic delay element 1000 is placed between microphone transducer 1002 and sensor PCB 1004. The delay element effectively increases the acoustic path 1006 to the transducer 1002, equalizing the path lengths 1006 and 1008 on opposing sides of the transducer 1002.

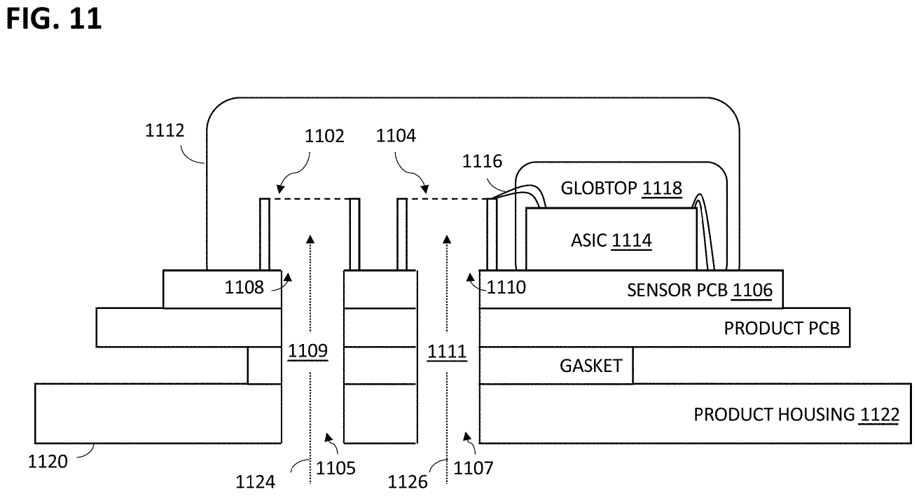

FIG. 11 depicts another device configured to reduce the effect of the unwanted package resonances. In this case, two MEMS transducers 1102 and 1104 are used in a differential configuration. MEMS transducers 1102 and 1104 are both mounted on or otherwise supported by sensor PCB 1106 above sound port 1108 and 1110 respectively and encapsulated under lid 1112. MEMS transducer 1104 is connected to ASIC 1114 via wirebonds 1116, MEMS transducer 1102 is also connected to ASIC 1114 through wirebonds not drawn in FIG. 11, Alternatively, the microphone may include a second ASIC to which MEMS transducer 1102 is connected. In other instances, MEMS transducers 1102 and 1104 may be mounted on PCB 1106 using flip chip technology and be electrically connected to the one or more ASICs through conductive traces on PCB 1106. The ASIC 1114 is encapsulated in globtop 1118 for protection. As previously described, when a sound wave travels along the direction that is parallel to edge 1120 on the product housing 1122, air will flow into one acoustic channels (i.e. 1109) and out of the other (i.e. 1111) through sound ports 1105 and 1107 embedded in product housing 1122. As a result, the motion of the air at the first MEMS sensor 1102 is out of phase with that of the second MEMS sensor 1104. When the package experiences resonance, sound waves traveling along any direction including those perpendicular to edge 1120 will enter sound ports 1105 and 1107. In this scenario, air will flow into both acoustic channels 1109 and 1111 in phase along paths 1124 and 1126 as illustrated. As a result, the motion of air around the first MEMS sensor 1102 and the second MEMS sensor 1104 are in phase. An output of the microphone is formed by subtracting the signal generated by the two MEMS sensors 1102 and 1104, effectively cancelling or significantly attenuating any in-phase components, while the signal due to out-of-phase motion remains, e.g., is boosted. As a result, a higher sensitivity is achieved for sound flowing parallel to edge 1120, and unwanted signal due to package resonance is eliminated or reduced.

Until now, the effect of the added volume in the package introduced by the addition of an ASIC has been ignored. In the above figures, it is assumed that air flowing through a first sound port, or inlet, will subsequently flow out a second sound port, or outlet. However, the additional volume of air introduced in the package above the ASIC provides a secondary path for airflow. In other words, the acoustic paths seen through both sides of the MEMS transducer are not symmetric and sensor directionality may be compromised.

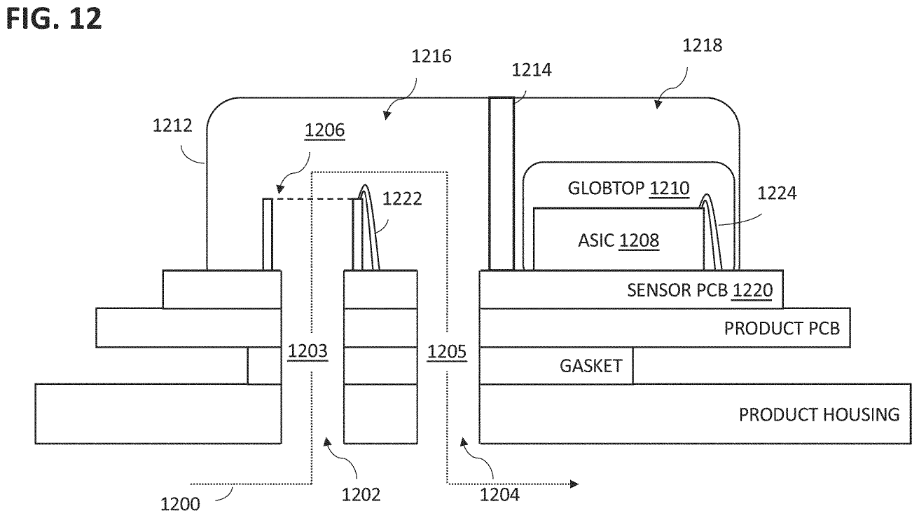

Turning now to FIG. 12, another device configured to maintain sensor directionality using a wall is depicted. A dividing wall 1214 is added between the MEMS transducer 1206 and the ASIC 1208 to isolate the air volume 1216 enclosed by lid 1212 above the MEMS transducer 1206 from the air volume 1218 above the ASIC 1208. The use of wall 1214 prevents a sound wave 1200 from flowing into air volume 1218. Instead, the sound wave 1200 is forced to travel only in and out of the sound ports 1202 and 1204 and associated acoustic channels 1203 and 1205, This avoids unwanted package resonances, especially at higher frequencies of sound, and maintains symmetry in the air volume 1216 enclosed by the package lid 1212, sensor PCB 1220, and wall 1214. The wall 1214 may be placed such that the MEMS transducer 1206 is positioned in the center of the cross section of air volume 1216.

In some instances, the wall 1214 may be a part of or connected to sensor PCB 1220, lid 1212, or both. In alternative examples, there may exist an air gap between the wall 1214 and lid 1214, between the wall 1214 and PCB 1220, or both. If there exists an air gap, it may be sufficiently small such that air is restricted from flowing between air volumes 1216 and 1218. The wall 1214 may have a straight or curved profile. For example, the cross-sectional profile of wall 1214 may be rectangular, elliptical, triangular, hexagonal, or any other geometrical shape. The wall may include a metal, plastic, ceramic, or any other material commonly used in MEMS sensor packages. In some instances, the wall 1214 may include two or more walls. In one such example, a first wall may extend from the lid 1214 to a certain distance from the PCB 1220 while a second wall extends from the PCB 1220 to a certain distance from the lid 1212. The first and second wall may have an air gap between them. In another instance, wall 1214 may have one or multiple holes, or windows.

The MEMS transducer 1206 may be electrically connected to sensor PCB 1220 through wire bonds 1222. The ASIC 1208 may also be connected to the sensor PCB 1220 through wire bonds 1224. Conductive traces on PCB 1220 may then connect the MEMS die 1206 to the ASIC 1208, In some instances, the wall 1214, may include a hole, or air gap, through which wire bonds extend and electrically connect the MEMS transducer 1222 and ASIC 1208. In other instances, flip-chip packaging techniques may be used to avoid the use of wirebonds altogether.

In alternative examples of the disclosed devices, the globtop 1210, may be made relatively large to minimize the air volume 1218. For example, the globtop 1210 may be placed such that the air gap between the globtop 1210 and the top edge of lid 1212 is minimized. In this scenario, the vertical wall 1214 may be removed partially or completely, and the globtop 1210 used in its place. In an alternative example, the globtop 1210 may come in contact with wall 1214. In another alternative example, another volume of air may be enclosed within the package under lid 1212, equal in volume to air volume 1218, but on the opposite side of the MEMS transducer 1206 as the ASIC 1208 and air volume 1218. Any combination of techniques may be used to maintain symmetry within the package around the MEMS die 1206 and preserve the directionality of the device. Other examples of the disclosed devices may maintain a symmetric air volume around the MEMS transducer in combination with any of the features described in the above figures.

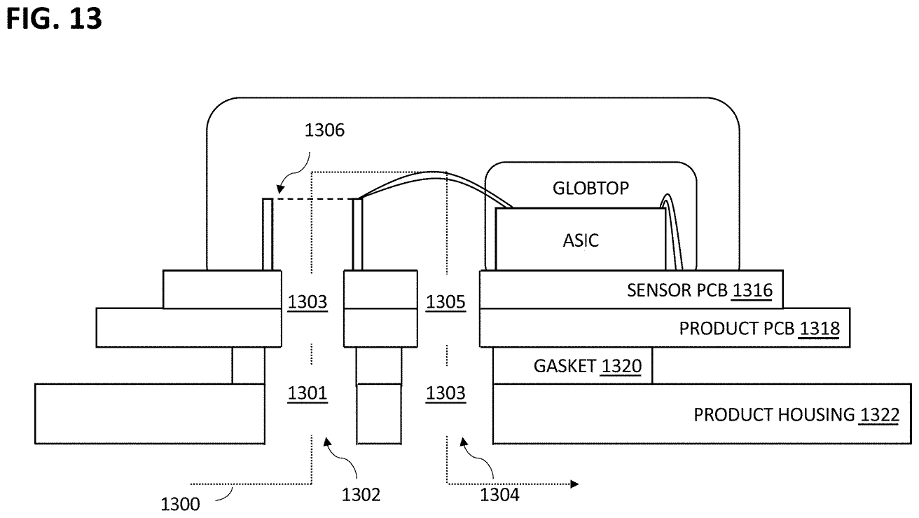

Several modifications to the package may be made to increase the sensitivity of the device. In FIG. 13, a dimension (e.g., the diameter) of the sound channels 1301 and 1303 in the product housing 1322 that are coupled to sound ports 1302 and 1304 is larger than a dimension (e.g., the diameter) of the acoustic channels 1303 and 1305 that run through the product PCB 1318 and sensor PCB 1316. As a result, the change in volume of the path experienced between the first acoustic channels 1301 and 1303 and the second acoustic channel 1303 and 1305 cause an acceleration of the airflow 1300. The MEMS transducer 1306 is placed at the output of the channel 1303 where the air motion is accelerated, thus increasing the sensor's sensitivity. The transition from a larger diameter channel (1301, 1303) to a smaller diameter channel (1303, 1305) may occur at the interface between the product housing 1322 and gasket 1320, the gasket 1320 and product PCB 1318, or the product PCB 1318 and sensor PCB 1316. Alternatively, the transition may take place within any single layer (1316, 1318, 1320, 1322). In some instances, a coating may be disposed on the package that reduces the friction between the airflow and the package walls to reduce losses as the air travels through the package.

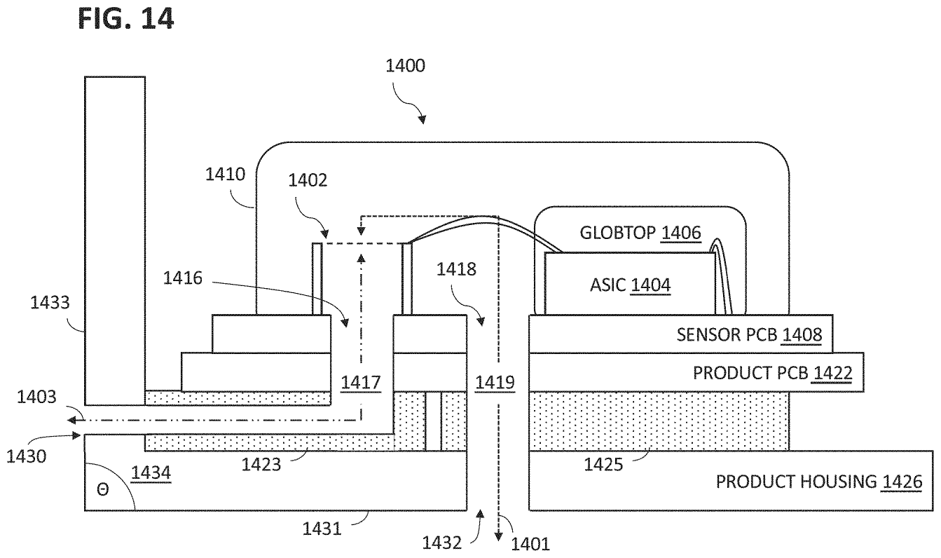

FIG. 14 describes an alternative example in which the sound ports of the product housing lay on two different surfaces. An electronic device has product housing 1426 with sound ports 1430 and 1432 which lay on two differing surfaces 1431 and 1433, respectively. The surfaces 1431, 1433 may define a corner or edge of the product housing. Embedded within the electronic device is an acoustic sensor (e.g., a microphone) 1400 with side-by-side sound ports 1416 and 1418. Microphone 1400 consists of a lid 1410 that encapsulated a MEMS transducer 1402 and ASIC 1404 protected by a globtop 1406. The lid 1410 creates an acoustic seal with sensor PCB 1408. The sensor PCB 1408 is mounted on or otherwise supported by the product PCB 1422 which is coupled to the product housing through gaskets 1423 and 1425. Sound ports 1416 and 1418 of the microphone 1400 lay on the same planar surface of PCB 1408 and are coupled to acoustic channels 1417 and 1419 which are further coupled to sound ports 1430 and 1432 of the product housing 1426. Bent acoustic channel 1417 is constructed such that the acoustic path lengths 1401 and 1403 are equal. In this example, the sound ports of the acoustic sensor 1400 are planar while the those of the product housing 1426 are not. In some examples, the corner of the edge connecting surface 1431 and 1433 may be a sharp or curved. The angle 1434 between surface 1431 and 1433 may be an acute angle, a right angle, or an obtuse angle.

In all the described examples of the disclosed devices, the geometry of the sound ports themselves may be shaped to maximize penetration of airflow into the package. Tapered sound ports (or sound ports with fillets) may also be used instead of sound ports with sharp edges. The cross-sectional profile of the sound ports or acoustic channels may be circular, rectangular, elliptical, triangular (e.g., a funnel), or any other geometry.

The sound ports may also be supplemented with mechanical structures on top or around them that further improves the sound wave penetration within the acoustic channels. These structures can be scatterers and reflectors that diffract and reflect sound wave close to the opening to re-direct the propagation toward the acoustic channels. In some instances, acoustic horns may be used with varying cross-sections to optimize the acoustic impedance along the opening and minimize the amount of acoustic energy reflected away from the opening. These structures can also be designed to introduce asymmetry between the openings and therefore enhance the acoustic wave propagating along a first direction and cancel acoustic waves propagating along a second direction. For example, various caps can be designed in this fashion to change the directional pickup patter of the sensor. Examples of directional pickup patterns include, but are not limited to, dipoles, cardioids, hypercardioids, and supercardioids.

In addition to the sound ports and acoustic channels, some examples of the described devices may contain other openings, such as ports, or valves in the package. These additional openings or valves can be used to interact with audio or non-audio related environmental stimulus. For example, they may be used to interact with DC or low frequency pressure changes, wind, temperature changes, external gasses and environmental contaminants, light, or electromagnetic waves. These openings may be constructed in such a way that they do not significantly influence the behavior of the device in response to acoustic waves have a frequency between 20 Hz-20 kHz. In one instance, the opening may allow air bursts to pass through the package due to excessive wind or shock without compromising the output of the MEMS transducer. In another instance, a channel with a varying cross section is introduced to reflect the acoustic contribution of wind while letting the alternating air flow in the audible spectrum through. These structures can be combined and integrated in any of the described packages.

In many electronic devices (e.g., consumer electronic devices), it in undesirable to have multiple holes in the product enclosure. In some instances, the holes in the product enclosure are limited to less than a few millimeters. As a result, it is useful to keep all the sound ports required for a directional microphone confined to an area smaller than that of the hole in the product enclosure, By doing this, only one acoustic channel and hole is drilled or otherwise formed in the product/electronic device enclosure. However, with traditional pressure-based directional microphones, this is not practical. Traditional pressure-based directional microphones respond to the pressure difference across two sound ports. If these sound ports are brought very close together, than the pressure difference becomes very small, and the sensitivity of the microphone is degraded significantly. Already, for spacings on the order of a few millimeters, the sensitivity of a pressure-gradient based directional microphone may be over 10× less than a traditional omnidirectional microphone.

By sensing acoustic flow instead of pressure, flow based directional microphones may eliminate or otherwise decrease the dependency on port spacing. As a result, even when the sound ports are brought very close together, sufficient sensitivity can be achieved.

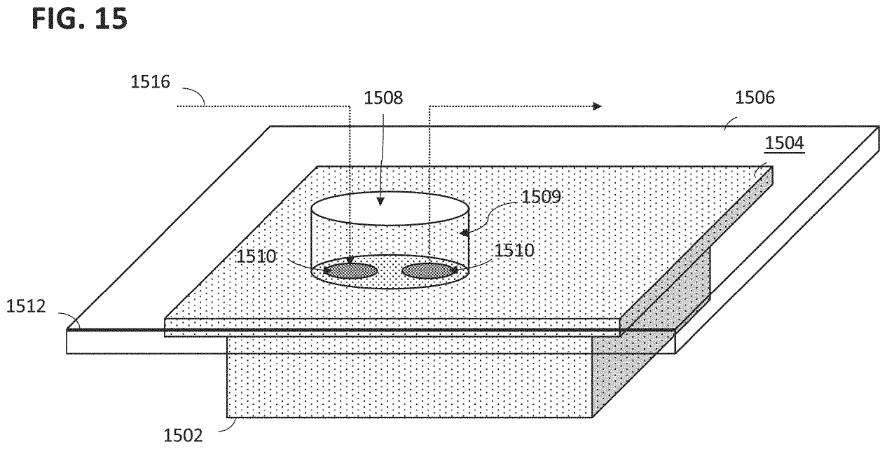

FIG. 15 depicts one such example of a directional microphone integrated into a product. The directional microphone 1502 is mounted onto or otherwise supported by a substrate layer or PCB 1504 which is further mounted onto an inner surface of the product housing 1506. The PCB 1504 may be the sensor PCB or the product PCB as previously described in the above figures. In the case where PCB 1504 is the sensor PCB, the product PCB is not drawn but may lay between the PCB 1504 and the product housing 1506. In the case where the PCB 1504 is the product PCB, there may be a gasket, a mesh, or both between PCB 1504 and product housing 1506. In general, any combination of a gasket, washer, acoustic mesh, adhesive, and/or other protective barriers may be placed in the acoustic channel between the product housing 1406 and microphone 1402. The product housing has a single sound port, or hollow hole, 1508 and acoustic channel 1509 which couples the air 1516 external to the product to the sound ports 1510 of the microphone 1502. The two sound ports 1510 sit on PCB 1504 and are completely encapsulated by the product inlet 1508. As sound 1516 travels parallel to edge 1512 on the product housing 1506, it can travel into the acoustic channel 1509 formed by the sound port, or inlet, 1508 through the product housing 1506 and into a first of two sound ports 1510 of microphone 1502. The airflow due to the sound wave 1516 can travel through the microphone 1502, out a second of the two sound ports 1510, and back out of the product sound port 1508. The product sound port 1508 and microphone sound ports 1510 may take any geometrical profile, such as but not limited to a circular, rectangular, elliptical, triangular, or hexagonal profile.

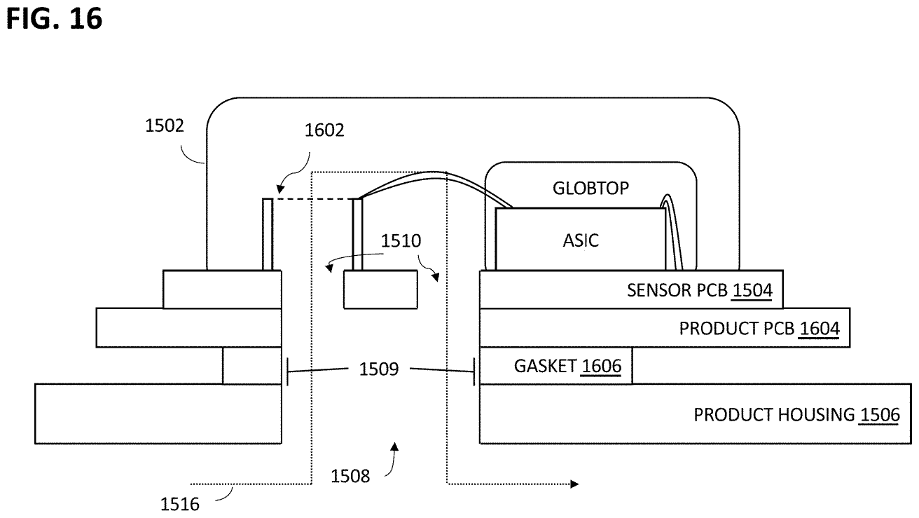

FIG. 16 depicts one such example of a cross section of the example described in FIG. 15. The single acoustic channel 1509 created by sound inlet 1508 extends through the product housing 1506, gasket 1606, and product PCB 1604. Sound ports 1510 couple the microphone 1502 to the acoustic channel 1509 formed by product inlet 1508. A sound wave 1516 flows into the product inlet 1508, into the first of the two sound ports 1510, and through a MEMS transducer 1602. The MEMS transducer 1602 may be configured to respond to the viscous drag induced from air flow through the transducer. The air flow then exits through the second of the two sound ports 1610 and out the product inlet 1508. Both sound ports 1510 lay within product inlet 1508. Any number of sound inlets into the microphone may exist within the acoustic channel and may not all take the same size and/or shape. The sound inlets may also be placed in different orientations relative to one another. The microphone may be or include two or more microphones whose sound ports share a common acoustic channel. In one example, the acoustic channel may be defined by, or otherwise include, only the product housing.

In each of the above-described examples, the same sensing principle may be applied to multiple axes, e.g., a second axis. For example, if it is useful to capture two directional signals, corresponding to sound flowing across the orthogonal X and Y vector directions, the same principle may be applied with a package containing four sound ports, where there are two sound ports placed along the X direction as described above and another two sound ports placed across the Y direction.

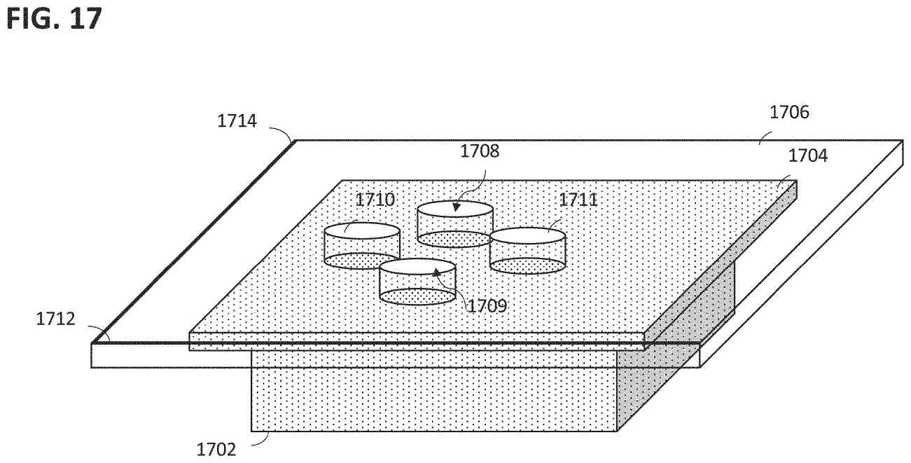

FIG. 17 depicts one such example in a bottom port microphone configuration. The directional microphone 1702 is mounted onto a PCB 1704 which is further mounted onto a surface of the product housing 1706. The PCB 1704 may be the sensor PCB or the product PCB as previously described in the above figures. In the case where PCB 1704 is the sensor PCB, the product PCB is not drawn but may lay between the PCB 1704 and the product housing 1706. In the case where the PCB 1704 is the product PCB, there may be a gasket, a mesh, or both between PCB 1704 and product housing 1706. In general, any combination of a gasket, washer, acoustic mesh, adhesive, and/or other protective barriers may be placed in the acoustic channel between the device housing 1706 and microphone 1702. Sound propagating parallel to the edge 1712 of the product housing 1706 creates a pressure difference between the ports 1710 and 1711. Air will flow into sound port 1710, through microphone 1702 and exit out of sound port 1711 and vice versa. However, the pressure difference created on sound ports 1708 and 1709 will remain the same and so no air will flow into them. The microphone 1702 may have a first output configured to output a signal corresponding to only the sound flowing parallel to edge 1712. Similarly, sound propagating parallel to the edge 1714 of the product housing 1706 creates a pressure difference between the ports 1708 and 1709. Air will flow into sound port 1708, through microphone 1702 and exit out of sound port 1709 and vice versa. However, the pressure difference created on sound ports 1710 and 1711 will remain the same and so no air will flow into them. The microphone 1702 may have a second output configured to output a signal corresponding to only the sound flowing parallel to edge 1714. The four sound ports 1708, 1709, 1710, 1711 may be coupled to four moving MEMS elements encapsulated in microphone. In an alternative example, the microphone 1702 may contain two MEMS elements. A first MEMS element may be coupled to either sound port 1708 or 1709 and a second MEMS element may be coupled to either sound port 1610 or 1611. In some instances, the placement sound ports 1708, 1709, 1710, and 1711 may be rotated relative to the edges 1712 and 1714. The spacing between sound ports 1708 and 1709 may be the same or different than the spacing between sound ports 1710 and 1711. Sound ports 1708, 1709, 1710, and 1711 may have equal diameter. In other instances, at least one of 1708, 1709, 1710, and 1711 may have a different diameter than the other sound ports.

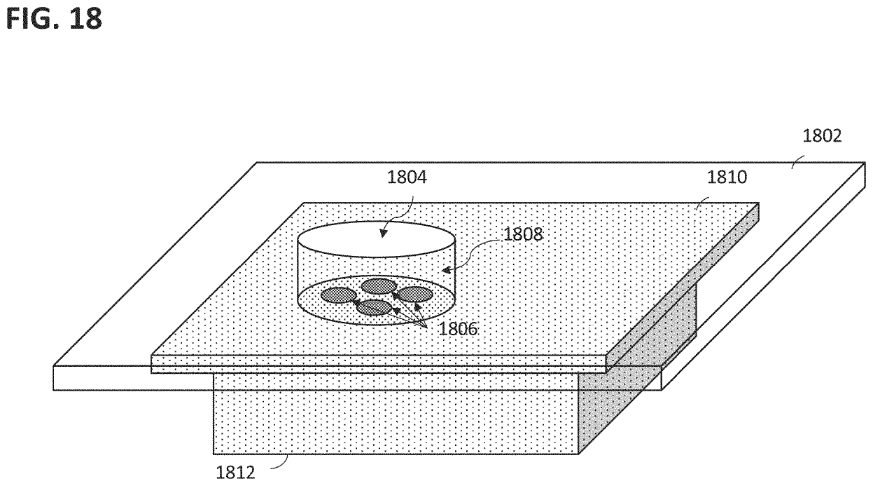

FIG. 18 depicts an alternative example of the dual direction microphone described in FIG. 17. In this case, as with the example described in FIG. 15, all the sound ports 1806 are fully encapsulated by the acoustic channel 1808 formed by the sound inlet 1804 in product housing 1802 and sound 1806 in the mounting structure 1810 of microphone 1812. In alternative examples, each of the four sound ports 1806 may include multiple sound ports.

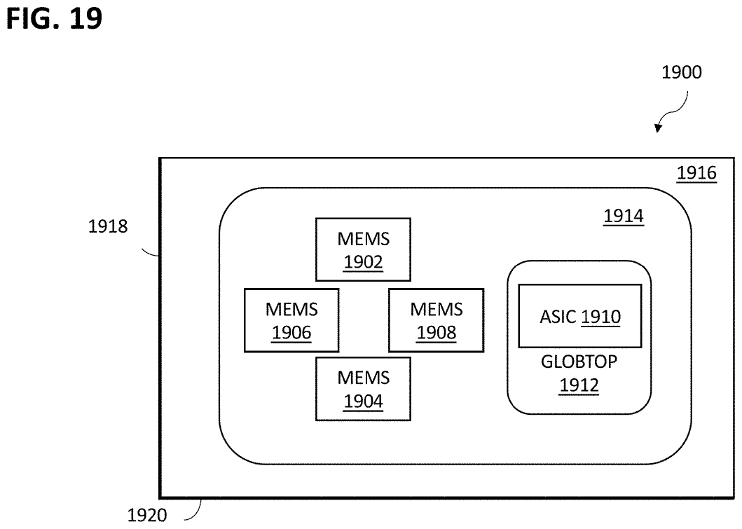

FIG. 19 depicts a top view of dual direction microphone as described in FIG. 17 and FIG. 18. The microphone 1900 consists of four MEMS transducers 1902, 1904, 1906, and 1908 connected to an ASIC 1910 and mounted on a printed circuit board 1916. The ASIC 1910 may be encapsulated by a globtop 1912 for protection and further placed under a lid 1914. The MEMS transducers 1902, 1904, 1906, and 1908 are coupled to the external environment through sound ports not shown but as described previously. In some instances, the microphone 1900 may contain two or more ASICs to which MEMS transducers 1902, 1904, 1906, and 1908 are coupled. The one or more ASICs may have one or more inputs and one or more outputs. The microphone 1900 may have a first output signal that is formed by taking the difference of the response from the MEMS transducer 1902 and 1904 and a second output signal that is formed by taking the difference of the response from the MEMS transducer 1906 and 1908. The first output signal may provide an estimation of only sound travelling parallel to the edge 1918. As sound travels parallel to the edge 1918, MEMS transducers 1902 and 1904 may move out of phase, effectively amplifying the first output signal. However, MEMS transducers 1906 and 1908 may move in-phase with one another, eliminating or attenuating the second output signal. In the same manner, the second output signal may provide an estimation of only sound travelling parallel to the edge 1920. As sound travels parallel to the edge 1920, MEMS transducers 1906 and 1908 may move out of phase, effectively amplifying the second output signal. However. MEMS transducers 1902 and 1904 may move in-phase with one another, eliminating or attenuating the first output signal.

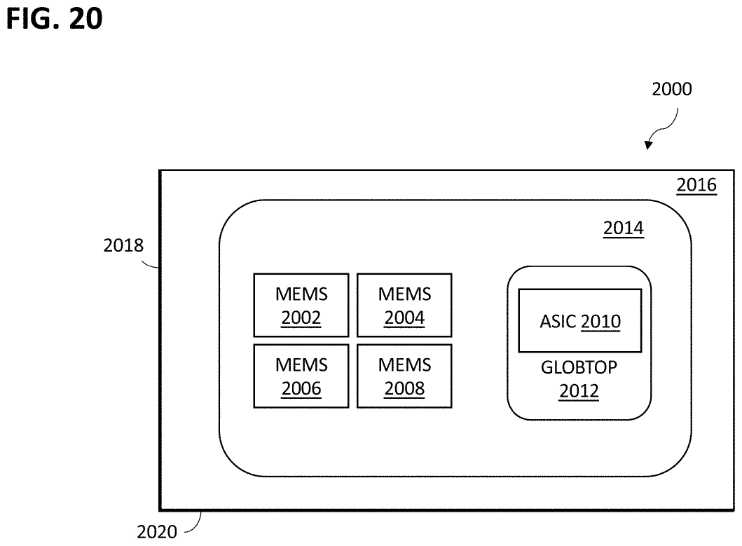

Finally, FIG. 20 depicts an alternative example where all four MEMS transducers are used for both the first and second output. As sound propagates in a direction parallel to edge 2020, MEMS transducer 2002 and 2006 may move in-phase with one another but out-of-phase relative to transducer 2004 and 2008. Thus, adding the signals from transducers 2002 and 2006 and subtracting the signals from transducer 2004 and 2008 may provide a first output signal of the sensor 2000 that is most sensitive to sound propagating parallel to edge 2020.

Similarly, as sound propagates in a direction parallel to edge 2018, MEMS transducer 2002 and 2004 may move in-phase with one another but out-of-phase relative to transducer 2006 and 2008. Thus, adding the signals from transducers 2002 and 2004 and subtracting the signals from transducer 2006 and 2008 may provide a second output signal of the sensor 2000 that is most sensitive to sound propagating parallel to edge 2018. This concept could extend to examples with more than four MEMS transducers. In examples with any number of MEMS transducers, the signal components that move in-phase are added together and subtracted to those that move out of phase. In some configurations, two or more of the MEMS transducers may be formed on a single silicon die or chip. The ASIC 2010 may include two or more ASICs, e.g., one ASIC for each output.

The flow-based nature of the MEMS sensors is useful in several ways. Traditional pressure (gradient) based directional microphones involve driving a sensing element (i.e. a diaphragm) by the force due to the pressure difference between the two sides of the diaphragm. A sensing element, i.e. a diaphragm, is used to seal the acoustic channel into a front chamber and back chamber. The front chamber is coupled to the external sound field by a first sound port, i.e. an inlet, and the back chamber in coupled to the external sound field by a second sound port, i.e. an outlet. The pressure difference between the front chamber/volume and the back chamber/volume drives the diaphragm motion. If these ports are spaced close together, the pressure difference seen at both these chambers will be very small, especially at low frequencies where the wavelength of sound is large. As a result, the driving force will be small, and the sensor will not have sufficient sensitivity. In order to remedy this, the ports need to be placed relatively far apart—typically greater than 10 mm. Because typical MEMS microphone packages have lengths <4 mm, this poses a problem, because both sound ports would not fit on the same package. Either acoustic tubes are attached to the MEMS package (increasing the effective port spacing) or a much larger package is used. Both of these approaches are undesirable as it leads to increased cost and system size.

Unlike traditional microphones which create a seal in the acoustic channel, a flow-based microphone allows air to pass through. It does not respond to the pressure-based forces across two sides of the diaphragm, but instead is driven by the viscous forces of the airflow dragging it back and forth—i.e., friction. By responding to airflow, the sensitivity of the structure with respect to the spacing between the two sound ports is reduced. Thus, it is possible to create a directional sound sensor with sufficient sensitivity where all the sound ports lay within the confines of the typical 4 mm×3 mm package area. The sensor performance is now optimized by designing a package that is made to allow the maximum amount of airflow through it with minimal losses (i.e. viscous boundary layer effects, etc.).

If a pressure-based microphone was placed in the packages of the above-described examples, where air flows through the acoustic channel, the microphone would not work.

The disclosed devices may include an enclosure enclosing a first volume of a viscous medium, a transducer positioned within the enclosure where at least one portion of the transducer is induced by viscous drag with respect to the viscous medium, a first port formed in the enclosure defining a first fluid path between the enclosed viscous medium and ambient viscous medium outside the enclosure adjacent the first port having a first impedance, and a second port formed in the enclosure defining a second fluid path between the enclosed viscous medium and ambient viscous medium outside the enclosure adjacent the second port having a second impedance. The first and second port may be positioned on the same surface. The viscous medium may be air. The transducer may be, or otherwise include, a microphone. The microphone may allow the air to flow through the transducer. In some cases, the device may include third and fourth ports defining a fluid path along a different direction than the first and second ports. The device may be configured to generate a first signal corresponding to the air flow along a first direction and a second signal corresponding to the air flow along a second direction. The transducer may include two moving elements having a spacing less than 1 mm. The device may include a second transducer. The first transducer and second transducer may have a spacing of less than 1 mm. The first and second directions may be orthogonal to one another. All the ports may be positioned within an area having a diameter of about 1 mm, 2 mm or 3 mm. The device may include a first transducer and a second transducer where outputs of the first and second transducers are combined to generate a signal corresponding to air flow along a first direction. The device may include a third transducer and a fourth transducer where outputs of the third and fourth transducers are combined to generate a signal corresponding to air flow along a second direction. A first acoustic channel to a first side of the microphone transducer may be made longer than a second acoustic channel to a second side of the microphone transducer so that the acoustic impedance of the first acoustic channel and the second acoustic channel are the same. A first acoustic channel to a first side of the microphone transducer may include an acoustic delay element so that the acoustic impedance of the first acoustic channel and acoustic impedance of a second acoustic channel to a second side of the microphone transducer are the same. A first acoustic channel to a first side of the microphone transducer may have a first acoustic impedance that is different than a second acoustic impedance of a second acoustic channel to a second side of the microphone transducer. A first port may have different dimensions than a second port to accelerate the fluid flow through one of the ports.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a housing;
an acoustic sensor disposed within the housing, the acoustic sensor comprising a microelectromechanical (MEMS) transducer;
a first port in the housing establishing a first acoustic path for air flow to the MEMS transducer; and
a second port in the housing establishing a second acoustic path for air flow to the MEMS transducer,
wherein the first and second acoustic paths have an equal path length.

2. The device of claim 1, wherein the MEMS transducer is configured as a flow transducer through which air flows.

3. The device of claim 1, wherein the housing comprises a surface in which the first and second ports are formed.

4. The device of claim 3, wherein the first and second ports are disposed side by side.

5. The device of claim 3, wherein the surface is planar.

6. The device of claim 3, wherein the first and second ports are oriented in a plane.

7. The device of claim 3, wherein the surface is disposed along an edge of the enclosure.

8. The device of claim 1, wherein the housing comprises first and second surfaces in which the first and second ports are formed, respectively.

9. The device of claim 8, wherein the first and second surfaces define a corner or edge of the housing.

10. The device of claim 1, further comprising an enclosure disposed within the housing, the enclosure encapsulating the MEMS transducer.

11. The device of claim 1, wherein the acoustic sensor comprises a printed circuit board on which the MEMS transducer is disposed, the printed circuit board comprising first and second sound ports for the first and second acoustic paths, respectively.

12. The device of claim 11, wherein the MEMS transducer comprises a sensing structure oriented transversely to the substrate.

13. The device of claim 11, wherein the first sound port is configured to define a bend in the first acoustic path within the printed circuit board.

14. The device of claim 11, wherein the first and second ports in the housing are larger than the first and second sound ports in the printed circuit board.

15. The device of claim 1, wherein the first and second acoustic paths lead to opposite sides of the MEMS transducer.

16. The device of claim 1, further comprising an acoustic delay element disposed along the first acoustic path.

17. The device of claim 16, wherein:
the acoustic sensor comprises a printed circuit board on which the MEMS transducer is disposed; and
the acoustic delay element is disposed between the printed circuit board and the MEMS transducer.

18. The device of claim 1, further comprising a product housing in which the housing and the acoustic sensor are disposed, wherein:
the housing comprises an enclosure for the acoustic sensor; and
the product housing comprises a hole that couples air to the first and second ports.

19. The device of claim 1, wherein the acoustic sensor comprises an enclosure in which the first and second MEMS transducers are disposed, an integrated circuit disposed within the enclosure, and a dividing wall that isolates a volume for the first and second MEMS transducers from a volume for the integrated circuit.

20. The device of claim 1, wherein:
the housing is configured as a product housing, and
a spacing between the first and second ports is greater than or about equal to a depth of the MEMS transducer relative to a surface of the product housing in which the first and second ports are formed.

21. A device comprising:
a housing;
an acoustic sensor disposed within the housing, the acoustic sensor comprising a first microelectromechanical (MEMS) transducer and a second MEMS transducer;
a first port in the housing establishing a first acoustic path for air flow to the first MEMS transducer; and
a second port in the housing establishing a second acoustic path for air flow to the second MEMS transducer,
wherein the first and second acoustic paths have an equal path length.

22. The device of claim 21, wherein the acoustic sensor comprises an integrated circuit configured to determine a difference between outputs of the first and second MEMS transducers.

23. The device of claim 21, wherein:
the first and second MEMS transducers are configured to capture sound propagating along a first direction;
the acoustic sensor comprises third and fourth MEMS transducers configured to capture further sound propagating along a second direction; and
the first and second directions are orthogonal to one another.
